(19) United States
(12) Patent Application Publication
(10) Pub. No.: US 2012/0199188 A1
(43) Pub. Date: Aug. 9, 2012

(54) METAL CONTACT FORMATION AND WINDOW ETCH STOP FOR PHOTOVOLTAIC DEVICES

(75) Inventors: Hui NIE, Cupertino, CA (US); Brendan M. Kayes, San Francisco, CA (US); Isik C. Kizilyalli, San Francisco, CA (US)

(73) Assignee: Alta Devices, Inc., Santa Clara, CA (US)

(21) Appl. No.: 13/023,844

(22) Filed: Feb. 9, 2011

(51) Int. Cl. H01L 31/0216; H01L 31/18; H01L 31/04; H01L 31/0224

(52) U.S. Cl. 136/256; 438/98; 438/69; 257/E31.119; 257/E31.124; 257/E31.001

(57) ABSTRACT

Embodiments of the invention generally relate to photovoltaic devices and more specifically, to metallic contacts disposed on photovoltaic devices and to the fabrication processes for forming such metallic contacts. In one aspect, a method for contact patterning on a photovoltaic device includes providing a semiconductor structure that includes a front contact layer and a window layer underneath the front contact layer, where the window layer also acts as an etch stop layer. At least one metal layer is deposited on the front contact layer, and a resist is applied on portions of the at least one metal layer. The at least one metal layer and the front contact layer are etched through to achieve the desired metallization.

### BACKGROUND OF THE INVENTION

1. Field of the Invention

Embodiments of the invention generally relate to photovoltaic devices, such as solar cells, and methods for fabricating such photovoltaic devices.

2. Description of the Related Art

As fossil fuels are being depleted at ever-increasing rates, the need for alternative energy sources is becoming more and more apparent. Energy derived from wind, from the sun, and from flowing water offer renewable, environment-friendly alternatives to fossil fuels, such as coal, oil, and natural gas. Being readily available almost anywhere on Earth, solar energy is becoming a viable alternative.

To harness energy from the sun, the junction of a solar cell absorbs photons to produce electron-hole pairs, which are separated by the internal electric field of the junction to generate a voltage, thereby converting light energy to electric energy. The generated voltage can be increased by connecting solar cells in series, and the current may be increased by connecting solar cells in parallel. Solar cells may be grouped together on solar panels. An inverter may be coupled to several solar panels to convert DC power to AC power.

Nevertheless, the currently high cost of producing solar cells relative to the low efficiency levels of contemporary devices has prevented solar cells from becoming a mainstream energy source and limiting the applications to which solar cells may be suited. One example of this is the formation of metal contacts. Current production methods of forming contacts on a solar cell can include forming a window layer on the absorber layer of a solar cell and forming a contact layer on the window layer. Front metal contacts are desired to be formed on the contact layer, but etching such metal contacts requires a chemical etchant that can also potentially etch into the underlying window layer, which has a thickness that needs to be controlled relatively precisely. Therefore, a different method is typically used to form the metal contacts.

For example, a lift-off process can be used, in which the metal layer is patterned into front metal contacts by using a patterning process that will not etch into the underlying layers. In this process, a resist or sacrificial layer is deposited on the contact layer, the resist layer is patterned to an inverse of the desired metal contact pattern, the metal is deposited on exposed portions of contact layer between the resist portions, and the resist layer is washed out. Then a separate wet chemical etch step is performed to remove the exposed portions of the contact layer in the areas between the metal layer contacts, where a chemical etchant can be used on the contact layer that will not attack the window layer.

However, a problem with lift-off processes is that these processes tend to be expensive and slower than other processes, and therefore not as suitable for large and high-volume production processes. In addition, when using a lift-off process it may not be possible to make the metal contacts as thick as desired for some types of photovoltaic devices.

Accordingly, there is a need for increased efficiency and production compatible methods for forming metal contacts in photovoltaic devices.

### SUMMARY OF THE INVENTION

Embodiments of the invention generally relate to photovoltaic devices such as solar cells, and more specifically, to the metallic contacts disposed on photovoltaic devices, and to the fabrication processes for forming such metallic contacts.

In one embodiment, a method for contact patterning on a photovoltaic device includes providing a semiconductor structure including a front contact layer and a window layer underneath the front contact layer, where the window layer also acts as an etch stop layer. At least one metal layer is deposited on the front contact layer, and a resist is applied on portions of the at least one metal layer. The at least one metal layer and the front contact layer are etched through to achieve the desired metallization.

Some embodiments of the method can include one or more various features. For example, the at least one metal layer can include nickel (Ni) and copper (Cu), and/or the window layer can include a phosphide, such as aluminum gallium indium phosphide (AlGaInP). The front contact layer can be a heavily doped gallium arsenide (GaAs) contact layer. The depositing can include blanket depositing a contact metallization on the front contact layer. The providing of a resist can include lithographically patterning the at least one metal layer by leaving resist where metallization is desired. The etching through the at least one metal layer and the front contact layer can include using a wet etchant, which can include, e.g., sulfuric acid (H₂SO₄).

In another embodiment, a method for patterning one or more metal contacts on a photovoltaic device includes providing a semiconductor structure, the semiconductor structure including a front contact layer and a window layer underneath the front contact layer, where the window layer also acts as an etch stop layer. At least one metal layer is deposited on the front contact layer using a sputtering or evaporation process, and a resist is applied on portions of the metal layer(s). One or more areas of the metal layer(s) that are not covered by the resist are electroplated to form one or more metal contacts. The resist is removed and both the metal layer(s) and the front contact layer are etched in areas of the metal layer(s) not covered by the one or more metal contacts.

In another embodiment, a photovoltaic device includes at least one semiconductor layer, a window layer deposited on the at least one semiconductor layer where the window layer includes an etch stop material resistant to an etchant during an etching process, a front contact layer deposited on the window layer and etched in a metallization pattern, and at least one metal contact deposited on the front contact layer. The metal contact etched in the metallization pattern is at least 5 μm thick.

The embodiments of metallic contacts and their formation described herein provide an etching of a metal layer and a contact layer while using an etch stop layer in a semiconductor structure which prevents further etching. This allows patterning of the front metal layer and etching of the contact layer in one step with one etching chemistry, where the etching is stopped where needed. Such innovations can allow for greater efficiency and flexibility in resulting photovoltaic devices and in forming such when compared to conventional solar cell fabrication processes.

### BRIEF DESCRIPTION OF THE DRAWINGS

FIG. 1 is a cross sectional view of a semiconductor structure in accordance with one embodiment described herein;

FIG. 2 depicts a cross-sectional view of the semiconductor structure of FIG. 1 in which metal layer(s) have been deposited;

FIG. 3 depicts a cross-sectional view of the semiconductor structure of FIG. 2 in which resist has been coated and patterned;

FIG. 4 depict a cross-sectional view of the semiconductor structure of FIG. 3 in which metal layer(s) and contact layer have been etched;

FIG. 5 depicts a cross-sectional view of the semiconductor structure of FIG. 4 in which resist has been removed; and

FIG. 6 is a flow diagram illustrating a method for forming metal contacts in accordance with some embodiments disclosed herein;

FIG. 7 depicts a cross-sectional view of a semiconductor structure in accordance with another embodiment described herein, in which resist has been coated;

FIG. 8 depicts a cross-sectional view of the semiconductor structure of FIG. 7 in which electroplating has been applied to the structure;

FIG. 9 depicts a cross-sectional view of the semiconductor structure of FIG. 8 after the resist has been removed;

FIG. 10 depicts a cross-sectional view of the semiconductor structure of FIG. 9 after metal layer(s) and contact layer have been etched.

FIG. 11 is a flow diagram illustrating a method for forming metal contacts in accordance with other embodiments disclosed herein.

### DETAILED DESCRIPTION

Embodiments of the invention generally relate to photovoltaic devices and processes, and more specifically to photovoltaic cells, metallic contacts formed on the photovoltaic cells, and the fabrication processes for forming such photovoltaic cells and metallic contacts. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

Embodiments of metallic contact formation described herein provide an etching of a metal layer and a contact layer while using an etch stop layer in a semiconductor structure, which prevents further etching into the device. This allows patterning of the front metal layer and etching of the contact layer in one step with one etching chemistry, where the etching is stopped where needed. Such innovations can allow for greater efficiency and flexibility in forming photovoltaic devices when compared to conventional solar cell fabrication processes.

Doping concentrations are referred to in the descriptions of semiconductor device embodiments. Herein, “doping concentration” refers to the concentration of active dopant in a material, i.e., the majority carrier concentration.

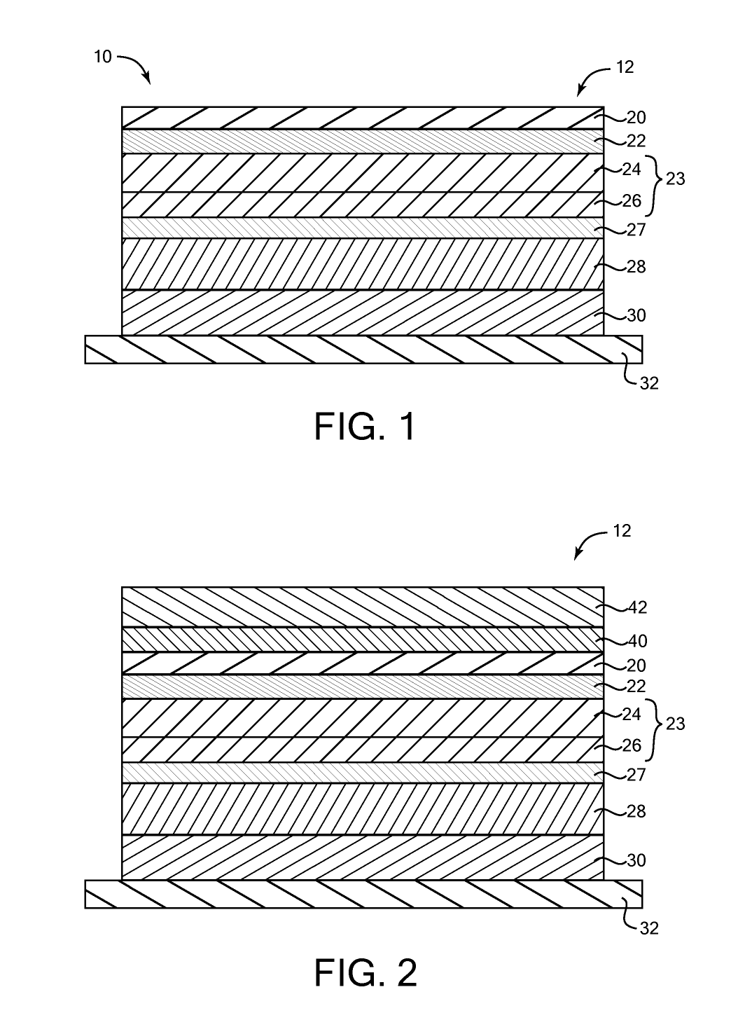

FIG. 1 illustrates a cross-sectional view of a portion of a photovoltaic device 10 which in the described embodiment includes a gallium arsenide (GaAs) based semiconductor structure 12. The structure 12 can be formed using a variety of layers and materials. For example, in some embodiments, the gallium arsenide based structure 12 can include an n-type film stack containing n-doped gallium arsenide materials disposed over a p-type film stack which contain p-doped gallium arsenide materials. Each of the n-type film stack and the p-type film stack independently contains multiple layers of varying compositions of materials. The n-type film stack can be facing the front side while the p-type film stack is on the backside of the structure. In other embodiments, the p-type film stack can be facing the front side and the n-type film stack facing the backside.

In one example, multiple layers of epitaxial materials containing varying compositions are deposited within the photovoltaic device 10. The various layers of epitaxial materials may be grown or otherwise formed by deposition process such as a chemical vapor deposition (CVD) process, a metal organic CVD (MOCVD) process, or a molecular beam epitaxy (MBE) process. The layers may be made of Group III-V materials and are thin films of epitaxially grown layers which can contain gallium arsenide, aluminum gallium arsenide, aluminum gallium indium phosphide, aluminum indium phosphide, alloys thereof, or combinations thereof. In some embodiments, the epitaxially grown layers may be formed by growing Group III-V materials during a high growth rate vapor deposition process. High growth rate processes and other device characteristics are described in greater detail in U.S. patent application Ser. No. 12/939,050, filed Nov. 3, 2010 and incorporated herein by reference in its entirety.

In some embodiments, the process of forming device 10 includes heating a wafer to a deposition temperature of about 550° C. or greater (or other ranges) within a processing system, exposing the wafer to a deposition gas containing a chemical precursor, such as gallium precursor gas and arsine for a gallium arsenide deposition process, and depositing a layer containing gallium arsenide on the wafer. The high growth rate deposition process can be utilized to deposit a variety of materials, including gallium arsenide, aluminum gallium arsenide, aluminum gallium phosphide, aluminum gallium indium phosphide, aluminum indium phosphide, aluminum arsenide, alloys thereof, dopant variants thereof, or combinations thereof. In some embodiments, a deposition gas can be formed by combining or mixing two, three, or more chemical precursors within a gas manifold prior to entering or passing through a showerhead, or formed by combining or mixing two, three, or more chemical precursors within a reaction zone after passing through the showerhead. The deposition gas can contain one or multiple chemical precursors of gallium, aluminum, indium, arsenic, phosphorus, or others. The deposition gas can also contain one, two or more carrier gases, which can also be combined or mixed with the precursor gases prior to or subsequent to passing through the showerhead. For example, the carrier gas can contain hydrogen (H₂), nitrogen (N₂), a mixture of hydrogen and nitrogen, argon, helium, or combinations thereof. The deposition processes for depositing or forming Group III-V materials, as described herein, may be conducted in any of a variety of types of deposition chambers.

In the example shown in FIG. 1, the semiconductor structure 12 can be formed including the use of an epitaxial lift-off (ELO) process or other process. For example, if an ELO process is used, a growth wafer, buffer layer(s) on the growth layer, and sacrificial layer on the buffer layer(s) can be provided (not shown). The sacrificial layer is also utilized to form the lattice structure for the subsequently and epitaxially grown layers contained within the structure 12. During a fabrication process, in one embodiment, the layers shown in structure 12 can be deposited on the sacrificial layer in the order from top to bottom in structure 12.

In some embodiments, the ELO process can include exposing the photovoltaic device to a wet etch solution in order to etch the sacrificial layer and to separate the gallium arsenide based structure 12 from the growth wafer. The wet etch solution can contain hydrofluoric acid, and can also contain various additives, buffers, and/or surfactants. The wet etch solution selectively etches the sacrificial layer while preserving the gallium arsenide based structure 12 and the growth wafer. Once separated, the gallium arsenide based structure 12 shown in FIG. 1 may be further processed to form a variety of photovoltaic devices, including photovoltaic cells and modules. Other embodiments can use other processes to form the structure 12 shown in FIG. 1. For example, the semiconductor structure layers can be deposited on a growth wafer.

In some embodiments, the semiconductor structure 12 can include adjacent layers such as an optional semiconductor front contact layer 20, a phosphide front window layer 22, a number of device layers 23, a metal back contact and reflector layer 28, an adhesive layer 30, and a backing 32. For example, in one embodiment, an n-type film stack can include an n-type contact layer 20, the phosphide front window layer 22, and an n-type absorber layer 24 formed adjacent the front window 22. A p-type film stack can include a p-type emitter layer 26 and a metallic contact and reflector layer 28 formed adjacent to the p-type emitter layer 26. The n-type and p-type stacks can be p-type and n-type, respectively, in other embodiments.

The optional contact layer 20 can contain Group III-V materials, such as gallium arsenide, depending on the desired composition of the final photovoltaic unit. In some embodiments, the contact layer 20 can be heavily doped, for example n-doped, and can be doped in some embodiments with a dopant such as silicon (Si), Selenium (Se), or Tellurium (Te). For example, the doping concentration may be within a range greater than about 1×10¹⁸ cm⁻³, such as greater than 5×10¹⁸ cm⁻³, for example, from greater than about 1×10¹⁸ cm⁻³ to about 1×10¹⁹ cm⁻³. Some embodiments provide a contact layer having gallium arsenide with an n-doped concentration of 5×10¹⁸ or greater, which allows an ohmic contact between metal layers and the semiconductor contact layer 20 without requiring an annealing step, as described in copending U.S. patent application Ser. No. ______, entitled, “Non-annealed Metal Contact to Semiconductor Material,” filed on an even date herewith, and incorporated herein by reference in its entirety. The contact layer 20 may be formed at a thickness of about 10 nm or greater, such as about 50 nm. In some embodiments, the contact layer 20 can be formed prior to an ELO process that separates the structure 12 from the growth wafer, or formed at a later stage subsequent to such an ELO process.

A phosphide front window 22, also known as a passivation layer, may be formed adjacent the contact layer 20. In some embodiments, the window 22 is made of aluminum gallium indium phosphide (AlGaInP), alloys thereof, derivatives thereof, or combinations thereof. For example, one embodiment can use AlGaInP in the molar ratios of Al_{0.3}Ga_{0.22}In_{0.48}P. Some embodiments can in general use the molar ratios of AlₓGa_{y}In_{1-x-y}P. In other embodiments, a different phosphide material can be used, such as aluminum indium phosphide (AlInP), alloys thereof, derivatives thereof, or combinations thereof. For example, one embodiment can use AlInP in the molar ratios of Al_{0.52}In_{0.48}P. These materials can provide for a high band gap passivation.

In the embodiments described herein, the front window 22 is used as both an etch stop layer in the process of fabricating the structure, and as a window layer during operation of the finalized device 10. This is described in greater detail below.

In some embodiments, the front window 22 material can be doped. For example, in some embodiments in which window 22 is n-doped, the doping concentration can be within a range greater than about 1×10¹⁸ cm⁻³, such as greater than 3×10¹⁸ cm⁻³, for example, from greater than about 1×10¹⁸ cm⁻³ to about 1×10¹⁹ cm⁻³. In other embodiments, the front window 22 material can be non-doped. The front window 22 may be deposited to have a thickness within a range from about 5 nm to about 75 nm. For example, in the embodiment using Al_{0.3}Ga_{0.22}In_{0.48}1³ about 20-35 nm thickness can be deposited, and in the embodiment using Al_{0.52}In_{0.48}P about 15-30 nm thickness can be deposited. Other thicknesses can be used depending on the doping of front window 22, molar ratios, and passivation desired. The front window 22 may be transparent to allow photons of incident light to pass through the front window 22 on the front side of the gallium arsenide based structure 12 to other underlying layers.

In some embodiments, the front window layer 22 can contain multiple window layers. For example, the first, outermost window layer (e.g., the window layer closest to the front side of the structure 12) can contain a phosphide material as described above, while a second window layer can be disposed adjacent to the device layers 23. In some embodiments, the second window layer can contain a phosphide of different composition than the phosphide in the first window layer. For example, the first window layer can contain Al_{0.52}In_{0.48}P and the underlying second window layer can contain Al_{0.3}Ga_{0.22}In_{0.48}P. In some embodiments, the lower aluminum content of the second window layer is useful as being more resistant to the etching in a previous ELO process that formed the structure 12.

In some embodiments, the second window layer can contain any suitable material, such as aluminum gallium arsenide, and may be doped or undoped. Some embodiments can provide three or more window layers, and/or can provide a window layer having a material continuously graded from one material to another. Furthermore, the outermost window layer can be roughened or textured before an anti-reflective coating layer is applied (not shown).

The device layers 23 can be formed adjacent to the front window 22. For example, the device layers 23 can include an absorber layer 24 and an emitter layer 26. Some embodiments can provide the absorber layer 24 adjacent (or closer to) the front window 22 and the emitter layer 26 under (or further from) the front window 22, while other embodiments can provide the emitter layer adjacent (or closer to) the front window 22.

In some embodiments, the absorber layer 24 can contain a Group III-V compound semiconductor, such as gallium arsenide. Some embodiments can provide the absorber layer 24 to be monocrystalline. The absorber layer 24 can, for example, have only one type of doping, for example, n-doping, and for some embodiments, the doping concentration of the n-type absorber layer 24 may be within a range from about 1×10¹⁶ cm⁻³ to about 1×10¹⁹ cm⁻³, for example, about 1×10¹⁷ cm⁻³. In some embodiments, the thickness of the n-type absorber layer 24 can be within a range from about 300 nm to about 3,500 nm, such as from about 1,000 nm to about 2,500 nm (about 1.0 μm to about 2.5 μm), for example, 2,200 nm. The absorber layer can be n-type in some embodiments, or p-type in other embodiments.

An emitter layer 26, also referred to in some embodiments as a back window, can be formed adjacent to the absorber layer 24. The emitter layer 26 can, for example, be p-doped if the absorber layer is n-doped, or vice-versa. The emitter layer 26 can contain a Group III-V compound semiconductor for forming a p-n junction with the absorber layer 24. In some embodiments, the contact of the absorber layer 24 with the emitter layer 26 creates a p-n interface layer for absorbing photons. The emitter layer 26 can be monocrystalline and/or can be heavily doped. For example, the doping concentration of a p-doped emitter layer may be within a range from about 1×10¹⁷ cm⁻³ to about 1×10²⁰ cm⁻³, such as above 1×10¹⁸ cm⁻³. The thickness of the emitter layer 26 can be within a range from about 100 nm to about 500 nm, for example, about 300 nm. For some embodiments, the absorber layer 24 may have a thickness of about 800 nm or less, such as, for example, about 500 nm or less, such as within a range from about 100 nm to about 500 nm.

Additional layers (not shown) can be included in the device layers 23, for example between the absorber layer 24 and emitter layer 26, or adjacent to either of the layers 24 and 26. For example, an intermediate layer can be provided between the layers 24 and 26. Furthermore, a semiconductor back contact layer 27 can be provided at the bottom of device layers 23 and adjacent to the layer 28. For example, such a semiconductor back contact layer can be made of a non-metal Group III-V compound semiconductor, such as gallium arsenide. For example, in one example the semiconductor back contact layer 27 can be generally monocrystalline and p-doped, and for some embodiments, the doping concentration of the back contact layer 27 can be greater than 1×10¹⁸ cm⁻³, such as above 3×10¹⁸ cm⁻³. In one example, the contact portion of layer 27 can have a thickness within a range from about 10 nm to about 100 nm, for example, about 50 nm.

Optionally, a metal back contact and reflector layer 28 can be formed adjacent the device layers 23. In some embodiments, the metal back contact material includes the reflector characteristic. In some embodiments, the metal back contact layer 28 can contain one or more metal layers such as copper, silver, or gold, with or without an adhesion metal layer containing a metal such as nickel. The metal back contact and reflector layer 28 can in some embodiments have a thickness within a range from about 50 nm to about 10 μm or greater. In some embodiments, the metal back contact layer 28 can cover the whole back of the device without patterning. Some embodiments can use the metal back contact layer 28 to guide an ELO process in fabricating the semiconductor structure 12.

In some embodiments, an adhesive layer 30 can be formed adjacent to the metal back contact and reflector layer 28. The adhesive layer 30 provides good adhesion to the adjacent material of the back contact or reflector layers 28 of the structure 12 and provides adhesion of the upper layers of the structure 12 to a backing 32 that is placed adjacent to the adhesive layer 30. In some embodiments, the adhesive layer 30 can contain a material including PSA (Pressure Sensitive Adhesive) or EVA (Ethylene Vinyl Acetate). The backing 32 can provide additional strength to an array of solar cells or a solar panel including structure 12 and can provide protection to the structure 12. The backing material can be glass, polymer/plastic, or other material such as metal, a composite material, etc.

In other embodiments, the opposite type of doping can be used in the layers discussed above, and/or other materials can be used that can provide the described p-n junction. Furthermore, in other embodiments the layers can be deposited or formed in a different order than the order described above. Other embodiments can provide different materials, layers, doping, thicknesses, etc. in the structure 12.

FIG. 2 illustrates the photovoltaic structure 12 after one or more metal layers are deposited on the structure 12 of FIG. 1. The metal layer(s) contain contact materials, which are electrically conductive materials, such as metals or metal alloys. Preferably, the contact materials contained within the metal layers do not diffuse beyond (e.g., below) the semiconductor contact layer 20, either during the metal deposition process itself, or during any of the subsequent process steps utilized during the fabrication of the completed photovoltaic cell. Usually, the metal layer(s) contain multiple layers of the same or different contact materials.

The metal contact materials can have an ohmic contact to the contact layer 20 to allow current in the device 10 to scale linearly with voltage in forward and reverse bias. In some embodiments, the metal layers can have specific contact resistance of 3×10⁻³ Ω-cm² or less. In some embodiments, the semiconductor contact layer 20 is highly doped, such as at a doping concentration of about 5×10¹⁸ to about 1×10¹⁹ cm⁻³. This allows the metal layer(s) to form an ohmic contact with the contact layer 20 without any annealing, and allows a wide range of metals to be used, as described in copending U.S. patent application Ser. No. ______, entitled “Non-annealed Metal Contact to Semiconductor Material.” In other embodiments, a lower dopant concentration can be provided in the contact layer 20 and annealing can be used to provide an ohmic contact between the metal layer(s) and the contact layer 20.

In the example of FIG. 2, the metal layers include an adhesion metal layer 40 containing nickel (Ni) and a conductive metal layer 42 containing copper (Cu). In some embodiments, the nickel layer 40 is blanket deposited on the contact layer 20 using a technique such as sputtering or evaporation. A copper layer 42 is then blanket deposited on the nickel layer 40, again using a technique such as sputtering or evaporation. In one example, the nickel layer has a thickness of 3 to 10 nm, and the copper layer has a thickness of 70 to 100 nm. Other thicknesses can be used in other embodiments. The thickness of the conductive metal layers can vary based on the size of the cell being fabricated. For example, the conductive metal layer can be formed to a thickness of about 5 μm or greater (without electroplating as described below). In some embodiments, an alloy of copper and nickel can be used. In embodiments in which the conductive metal layer 42 contains a material with less than desirable adhesion, the adhesion metal layer can be deposited first to allow the conductive metal layer(s) to adhere to the contact layer 20.

A Ni—Cu metal layer 40-42 is advantageous in some embodiments in that it is inexpensive and provides ohmic (tunneling) contacts to n+ gallium arsenide in the contact layer 20 if the doping levels in the contact layer 20 are sufficiently high. Furthermore, nickel and copper layers are relatively easier to etch using a wet etchant than many other types of metals. For example, the metal layers 40-42 can be used as the front grid contact for a solar cell or other photovoltaic device 10.

Other metals can alternatively or additionally be used for the metal layers. For example, a high conductive metal such as silver (Ag) or aluminum (Al) can be used instead copper for the conductive metal layer 42. Other suitable conductive contact materials can include gold (Au), platinum (Pt), derivatives thereof, alloys thereof, or combinations thereof. Other metals can be used for the adhesion layer 40 instead of nickel, such as titanium (Ti), chromium (Cr), derivatives thereof, alloys thereof, or combinations thereof. Other embodiments can include three or more metal layers. In some embodiments, other fabrication methods can be used to deposit the metal layers 40 and/or 42.

In embodiments in which the doping concentration of an n-doped GaAs contact layer 20 is sufficiently high, such as 5×10¹⁸ cm⁻³ or greater, then the structure 12 does not have to be annealed to form an ohmic contact between the metal layers and the semiconductor contact layer 20; the ohmic contact will occur without annealing. This is described in greater detail in copending U.S. patent application Ser. No. ______, entitled “Non-annealed Metal Contact to Semiconductor Material,” previously incorporated by reference. In other embodiments, annealing can be performed on the structure 12 to form the ohmic contact between metal layer and contact layer, e.g. using palladium (Pd) and germanium (Ge) (or alloy of Pd and Ge) as the metal layers 40 and/or 42. In such cases, the annealing may in some embodiments create a mixed material in the metal contacts. Such material may have different etching properties than the component metals, such that an appropriate etchant for the resulting layers may be needed (and corresponding stopping material for etch stop window 22).

The metal layers 40 and 42 can be made much thicker when using the etching process described herein, compared to the limited thickness of the metal layers required in previously-used lift-off processes. For example, in the metal-patterning lift-off processes, the metal layer thickness is limited by the resist (or sacrificial layer) thickness. The resist typically is about 2-4 μm thick, which limits the metal layer to about 3 μm thick. In contrast, using the etching process of the described embodiments, it is possible to create metal contacts as thick as 5 μm or more (and electroplating can be used to create even thicker metal contacts, as described below). Thicker metal layers are desirable in many embodiments, as because there is less resistance, current flows better than in thinner layers. This reduces loss in the current generated by a solar cell. In addition, the thicker the metal contact layer, the narrower the contacts can be made without changing the overall resistance of the metallization, which is desirable in many applications. For example, in solar cell applications, thinner contacts cover less surface area of the solar cells and thus cause less shading from incident light and higher current and performance of the cells.

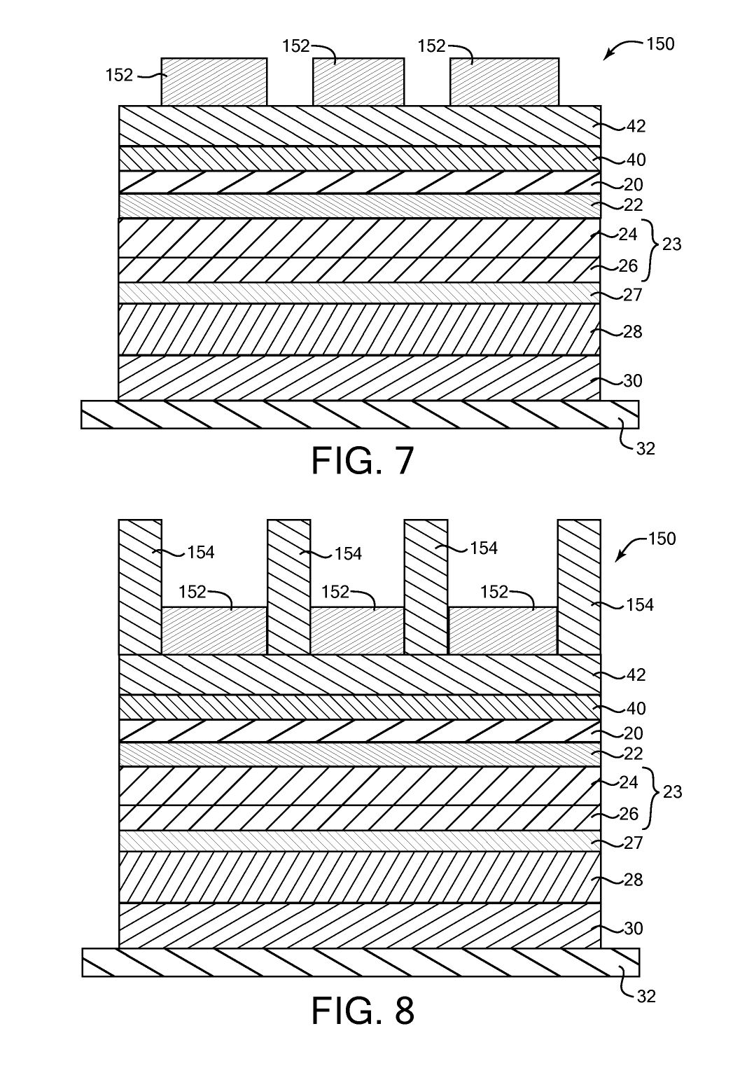

In other embodiments, the metal layers 40 and 42 can be made thin, and the metal layer(s) can be made thicker at a later time with another processing step. For example, electroplating can be used, e.g., electroplate the top metal layer 42 to create thicker metal contacts thicker. This embodiment is described in greater detail below with respect to FIGS. 7 to 10. The etching process of the described embodiments assist in such an embodiment to provide etch selectivity to help define thin features, for example, as well as the other advantages described herein.

In some alternate embodiments, the metal contact layer etching as described herein can be performed on the backside of the photovoltaic structure 12.

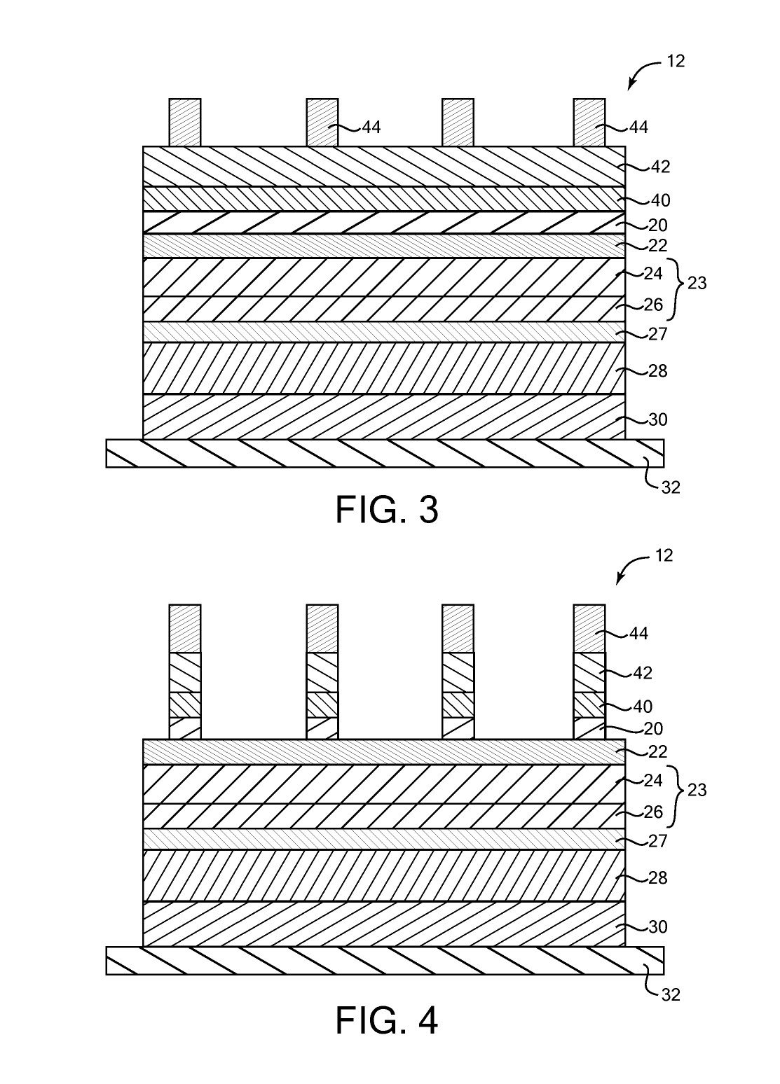

FIG. 3 illustrates the photovoltaic structure 12 after a resist 44 has been applied to the top surface and patterned. The structure 12 is coated with a resist layer, such as a photoresist or dry resist, in one or more layers (e.g., the resist layer can include one layer or multiple layers). For example, in some embodiments the resist can be spincoated S1818 or other photoresist, or a laminated dry film resist. The resist 44 can be softbaked if necessary, e.g., to drive away solvent from the resist, improve the adhesion of the resist to the underlying layer, anneal stresses resulting from coating the resist, etc.

After the structure has been coated with the resist, the resist layer is geometrically patterned to the desired metallization pattern. For example, in some embodiments the resist can be patterned using lithography, e.g., by exposure to radiation, such as UV radiation, through a resist mask that defines the areas of the resist surface that will be exposed to radiation and those that will be covered. The exposed resist is then developed or dissolved into the desired resist pattern using a developer, such as Microposit® MF®-319. The resist can be hardbaked if necessary, e.g., if a non-chemically amplified resist was used, to solidify the remaining photoresist.

The pattern used on the resist implements the desired metal contact pattern for the photovoltaic device 12. Resist is left on the metal layers 40-42 where the metallization is desired, i.e., in the locations where the metal contacts are desired.

FIG. 4 illustrates the photovoltaic structure 12 after a chemical etch of the metal layers and contact layer has taken place. The areas between the resist 44 are etched. In some embodiments, a wet chemical etchant is used to remove the areas of metal layers 40 and 42 and contact layer 20. For example, in the embodiment described above in which metal layers 40 and 42 are nickel and copper, respectively, an etchant that is a sulfuric acid (H₂SO₄), hydrogen peroxide (H₂O₂), and water (H₂O) mixture can be used. For example, in one embodiment the etchant can be H₂SO₄:H₂O₂:H₂O in the ratio of about 1:8:100 by volume, and the etching can be for a duration of about one to two (1-2) minutes. This etchant (or a similar etchant including H₂SO₄) attacks gallium arsenide and aluminum gallium arsenide layers, but will be stopped by a phosphide, such as the phosphide etch stop layer 22, and thus any substantial further etching of the lower device layers is prevented. Such an etchant is not commonly used to etch copper layers, but is useful in the embodiments described herein to etch metal layers and to allow the etch stop ability of the phosphide window layer 22. Thus, a strong enough chemical etchant can be used to etch both metal layers and a contact layer, with minimal etching of further layers. The etching process for etching through the metal layers 40 and 42 and the contact layer 20 does not need a lift-off process as in previous methods, thereby allowing a more efficient process.

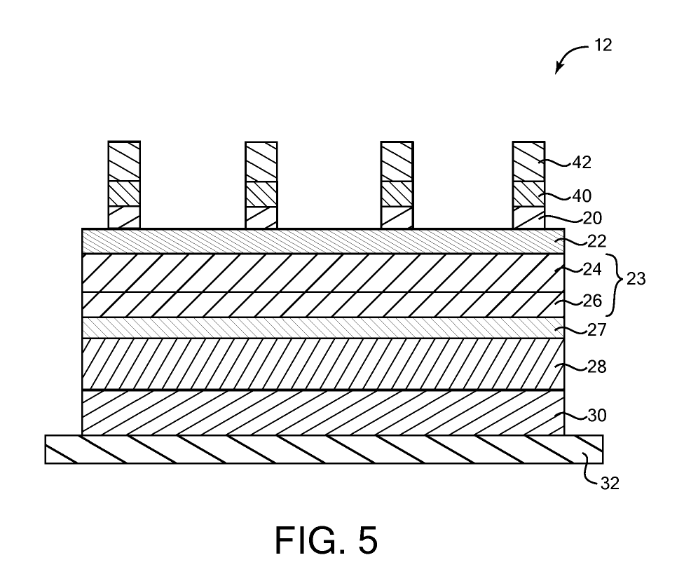

FIG. 5 illustrates the photovoltaic structure 12 after the resist 44 has been removed. For example, the resist can be removed using acetone followed by a rinse of isopropanol and drying with nitrogen (N₂). In some embodiments, the resist 44 can be removed using sodium hydroxide, or using potassium hydroxide or another base. After the resist is removed, the rest of the photovoltaic device 12 is then built as normal.

The embodiments described herein provide a layer of semiconductor material to be used as both an etch stop layer and a passivation/window layer to the solar cell. This allows both the front metal layer(s) and the underlying contact layer to be etched with a wet chemical etching process and with very little etching occurring in the window layer under the contact layer, and can be performed in a single step unlike the previous multiple step processing when using lift-off processes to pattern the metal contacts, in which a separate metal patterning step was performed. The etching of metal contacts as described herein allows highly precise dimensions for metal contacts to be formed, and with greater thickness (and less width) than allowed by lift-off processes.

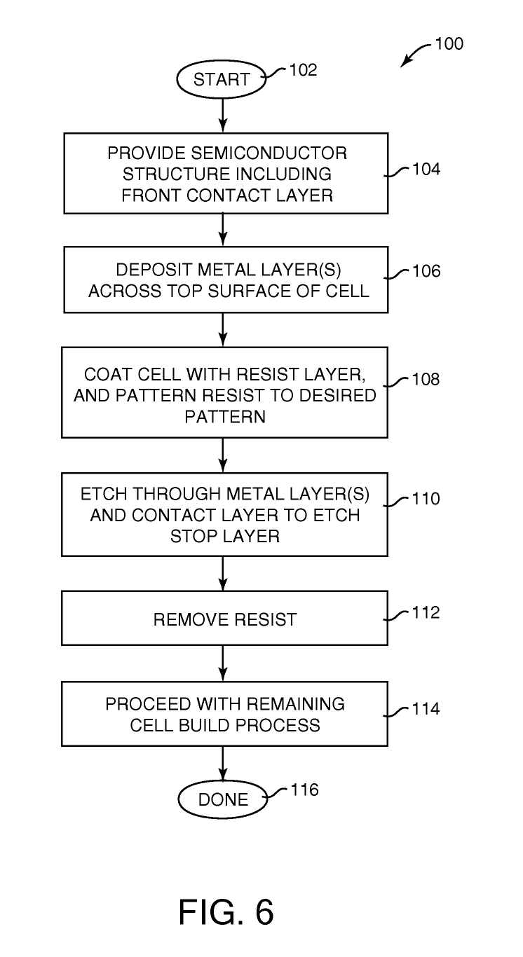

FIG. 6 is a flow diagram illustrating a method 100 for etching metal contacts as described by embodiments disclosed herein. The method starts at 102, and in step 104, a photovoltaic structure 12 is provided, which includes semiconductor layers up to a top semiconductor contact layer, as described above with reference to FIG. 1. In step 106, one or more metal layers (e.g., layers 40 and 42) are deposited on the contact layer, as described above with reference to FIG. 2. In step 108, structure 12 is coated with a resist layer, and the resist layer is patterned to provide the desired etch pattern for the metal layers, as described above with reference to FIG. 3.

In step 110, an etching procedure is performed to etch through the metal layer(s) and through the contact layer in a single step, as described above with reference to FIG. 4. The etchant is stopped by the etch stop layer 22, which in some embodiments includes a phosphide material. In step 112, the remaining resist is removed, and in step 114 the remaining steps of the device build process are continued as normal to fabricate the semiconductor structure 12 in a photovoltaic device. For example, a subsequent isolation etch step may be required to define the cell area, and other layers such as an anti-reflective coating layer can be deposited on the metal contact layer and exposed window layer portions. The process is complete at 116.

FIGS. 7-10 illustrate another embodiment of the photovoltaic device 10 including a semiconductor structure 150, where structure 150 includes additional metal plating on the metal contacts to increase the height of the contacts. FIG. 7 illustrates a structure 150 similar to the structure 12 described above with respect to FIG. 2, in which a conductive metal layer 42 is deposited on an adhesive metal layer 40, which is deposited on layers including an optional semiconductor contact layer 20, a phosphide front window layer 22, device layers 23, an optional semiconductor contact layer 27, metal back contact and reflector layer 28, adhesive layer 30, and a backing 32. The structure 150 can be fabricated using similar processes as described above for the structure 12 in FIG. 2.

Structure 150 includes a resist 152, which is deposited on the conductive metal layer 42. Resist 152 can be a photoresist or dry resist deposited first in a layer and optionally softbaked, similarly to the resist 44 described above with respect to FIG. 3. In some embodiments, the resist 152 can be deposited in multiple layers of different resist materials. The resist 152 is then geometrically patterned based on the desired metal contact geometry. However, unlike the embodiment of FIG. 3, the resist 152 is patterned as the inverse of the desired metal contact geometry such that resist is left in locations on metal layer 42 which are not to have metal contacts. For example, in some embodiments the resist can be patterned using lithography through a resist mask, where the exposed resist is then developed or dissolved into the desired resist pattern using a developer. The resist 152 can be hardbaked if necessary to solidify the remaining resist.

FIG. 8 illustrates the structure 150 after electroplating has been applied to the structure having resist 152 as shown in FIG. 7. Metal contacts 154 are deposited on the exposed regions of the metal layer 32 using an electroplating process. For example, the structure (or a portion thereof) can be immersed in a solution and a current applied to bias metal ions to move from an anode (not shown) to a cathode, which is the exposed portions of the conductive metal layer 42, thus coating those exposed portions and building further on electroplated portions to provide a greater thickness (the electroplated contacts 154 may also have greater width above the level of the resist 152 due to the electroplating, but this is generally not significant compared to the contact width dimension). Contacts 154 can have a thickness much larger than the metal layer 42; for example, in some embodiments the metal contacts 154 can be deposited to a thickness of about 5 μm or greater, such as about 10 to 12 μm.

The plated metal contacts 154 can contain the same conductive metal(s) that the conductive layer 42 contains. For example, in the embodiments in which conductive layer 42 contains copper, the plated contacts 154 can also contain copper. Alternatively, the contacts 154 can contain a different conductive metal than layer 42 and/or 40. Multiple layers of different conductive metals can be electroplated on the layer 42 in some embodiments. The desired characteristics of the contacts 154 are similar to those of the conductive metal 42 as described above.

Using an electroplating process allows the metal contacts of the semiconductor structure 150 to be much thicker than in the embodiments described above that use only metal layer deposition and etching. Thicker metal contacts allow the contacts to be made narrower without increasing the electrical resistance, which is advantageous in solar cell applications to increase efficiency and performance.

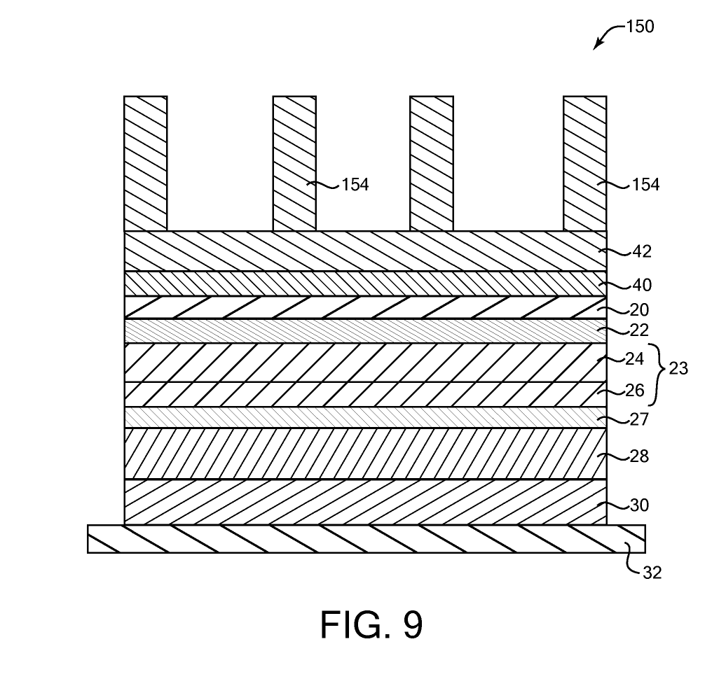

FIG. 9 illustrates the structure 150 after the resist 152 has been removed using any of a variety of resist removal techniques. For example, the resist 152 can be removed using acetone followed by a rinse of isopropanol and drying with nitrogen (N₂). In some embodiments, the resist 44 can be removed using sodium hydroxide, or using potassium hydroxide or another base.

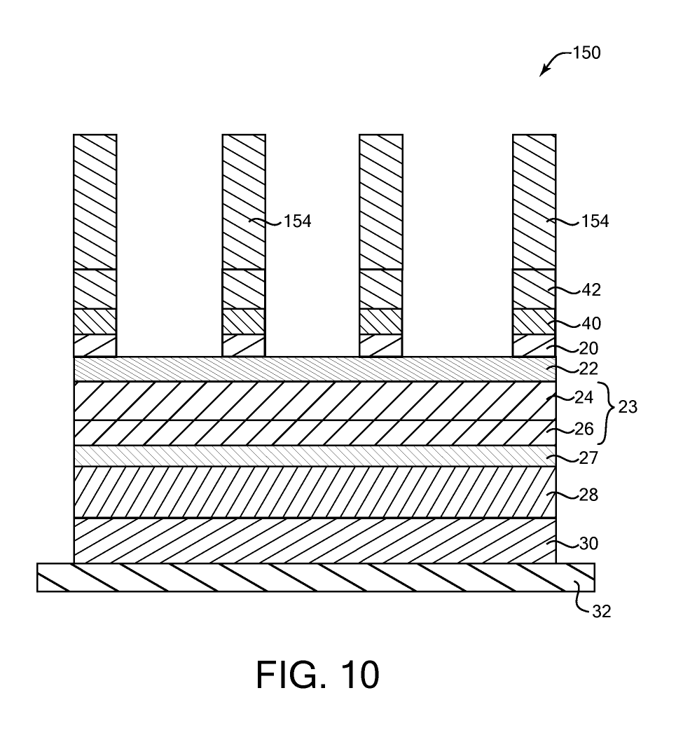

FIG. 10 illustrates the structure 150 after a chemical etch of the metal layers and contact layer has taken place. The areas between the resist contacts 154 are etched down to the phosphide window layer 22. This etch is similar to the one described above with respect to FIG. 4 and the structure 12. For example, in some embodiments, a wet chemical etchant can be used to remove the areas of metal layers 40 and 42 and contact layer 20. For example, in the embodiment described above in which metal layers 40 and 42 are nickel and copper, respectively, an etchant that is a sulfuric acid, hydrogen peroxide, and water mixture can be used. For example, in one embodiment the etchant can be H₂SO₄:H₂O₂:H₂O in the ratio of about 1:8:100 by volume, and the etching can be for a duration of about one to two (1-2) minutes, or other chemicals, chemical ratios, and etch times may be used. In some embodiments, the etchant may etch the plated metal contacts 154 in a small degree, which is generally not significant to the operation of the device. In other embodiments, a resist or a protective metal such as gold or tin (Sn) can be applied to the plated metal contacts 154 so that the etchant will not attack the contacts 154.

The resulting metal contacts include the portions of metal layers 40 and 42 as well as the plated metal contacts 154. This provides a much thicker metal contact than is possible using prior techniques, e.g. 10-12 μm thick.

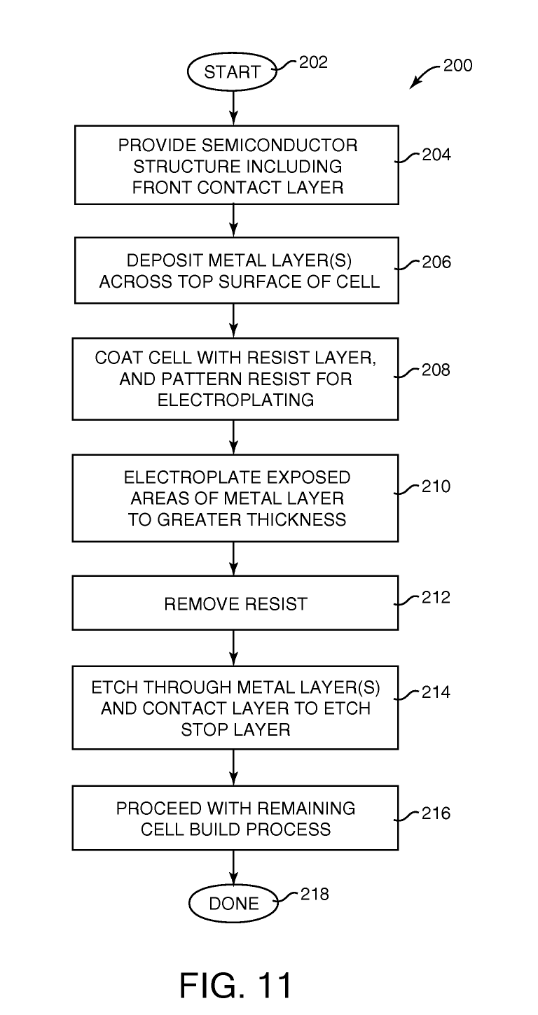

FIG. 11 is a flow diagram illustrating a method 200 for another embodiment of metal contact patterning as disclosed herein. The method starts at 202, and in step 204, a structure 12 is provided, which includes semiconductor layers up to a top semiconductor contact layer, as described above with reference to FIGS. 1 and 7. In step 206, one or more metal layers (e.g., layers 40 and 42) are deposited on the contact layer, as described above with reference to FIG. 2. In step 208, structure 12 is coated with a resist 152, and the resist is patterned for electroplating metal contacts, as described above with reference to FIG. 7.

In step 210, exposed areas of the top metal layer 42 outside the resist 152 are electroplated to provide metal contacts of greater thickness, as described above with reference to FIG. 8. In step 212, the resist 152 is removed as described above with reference to FIG. 9. In step 214, an etching procedure is performed to etch through the metal layers 40 and 42 and through the contact layer 20 in a single step, as described above with reference to FIG. 10. In step 216, the remaining steps of the device build process are continued as normal to fabricate the structure 12 in a photovoltaic device. For example, a subsequent isolation etch step may be performed to define the cell area, and other layers such as an anti-reflective coating layer can be deposited on the metal contact layer and exposed window layer portions. The process is complete at 218.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for contact patterning on a photovoltaic device, the method comprising:
providing a semiconductor structure, the semiconductor structure including a front contact layer and a window layer underneath the front contact layer, wherein the window layer also acts as an etch stop layer;
depositing at least one metal layer on the front contact layer;
applying a resist on portions of the at least one metal layer; and
etching through the at least one metal layer and the front contact layer to achieve the desired metallization.

2. The method of claim 1 wherein the at least one metal layer comprises nickel and copper.

3. The method of claim 1 wherein the at least one metal layer comprises a nickel layer deposited on the front contact layer and a copper layer deposited on the nickel layer.

4. The method of claim 1, wherein the window layer comprises a phosphide.

5. The method of claim 4, wherein the phosphide comprises at least one of: AlGaInP and AlInP.

6. The method of claim 1, wherein depositing comprises blanket depositing a contact metallization on the front contact layer.

7. The method of claim 1, wherein providing a resist comprises lithographically patterning the at least one metal layer by leaving resist where metallization is desired.

8. The method of claim 1, wherein the front contact layer is a heavily doped gallium arsenide (GaAs) contact layer.

9. The method of claim 1, wherein the etching through the at least one metal layer and the front contact layer includes using a wet etchant

10. The method of claim 9, wherein the wet etchant includes sulfuric acid (H₂SO₄).

11. A photovoltaic device fabricated using the process of claim 1.

12. A method for patterning one or more metal contacts on a photovoltaic device, the method comprising:
providing a semiconductor structure, the semiconductor structure including a front contact layer and a window layer underneath the front contact layer, wherein the window layer also acts as an etch stop layer;
depositing at least one metal layer on the front contact layer using a sputtering or evaporation process;
applying a resist on portions of the at least one metal layer;
electroplating at least one area of the at least one metal layer that is not covered by the resist to form one or more metal contacts;
removing the resist; and
etching through both the at least one metal layer and the front contact layer in areas of the at least one metal layer not covered by the one or more metal contacts.

13. The method of claim 12 wherein the at least one metal layer comprises nickel and copper and the metal contacts comprise copper.

14. The method of claim 12, wherein the window layer comprises a phosphide.

15. The method of claim 12, wherein the one or more metal contacts are at least 5 μm thick.

16. The method of claim 14, wherein the etching through the at least one metal layer and the front contact layer includes using a wet etchant, wherein the wet etchant includes sulfuric acid (H₂SO₄), hydrogen peroxide (H₂O₂), and water (H₇O).

17. A photovoltaic device comprising:
at least one semiconductor layer;
a window layer deposited on the at least one semiconductor layer, wherein the window layer includes an etch stop material resistant to an etchant during an etching process;
a front contact layer deposited on the window layer and etched in a metallization pattern; and
at least one metal contact deposited on the front contact layer, wherein the at least one metal contact is etched in the metallization pattern and is at least 5 μm thick.

18. The photovoltaic device of claim 17, wherein the at least one metal layer comprises nickel and copper.

19. The photovoltaic device of claim 17, wherein the etch stop material in the window layer comprises a phosphide.

20. The photovoltaic device of claim 17, wherein the front contact layer is a heavily doped GaAs contact layer.
